(19) United States
(12) Patent Application Publication
(10) Pub. No.: US 2024/0128372 A1
(43) Pub. Date: Apr. 18, 2024

(54) METHOD FOR MANUFACTURING A VERTICAL FIELD EFFECT TRANSISTOR STRUCTURE AND CORRESPONDING VERTICAL FIELD EFFECT TRANSISTOR STRUCTURE

(71) Applicant: Robert Bosch GmbH, Stuttgart (DE)

(72) Inventors: Christian Huber, Ludwigsburg (DE); Daniel Krebs, Aufhausen (DE)

(21) Appl. No.: 18/486,349

(22) Filed: Oct. 13, 2023

(30) Foreign Application Priority Data
Oct. 14, 2022 (DE) 10 2022 210 835.3

(51) Int. Cl. H01L 29/78; H01L 29/06; H01L 29/16; H01L 29/66

(52) U.S. Cl. CPC H01L 29/7813; H01L 29/0615; H01L 29/1608; H01L 29/66734

(57) ABSTRACT

A method for manufacturing a vertical field effect transistor structure and to a corresponding vertical field effect transistor structure. The vertical field effect transistor structure is provided with a semiconductor body having first and second connecting zones of a first conductivity type, a channel zone of the first or second conductivity type between the first and second connecting zone, a plurality of trenches extending into the semiconductor body, reaching into the first connecting zone from the second connecting zone through the channel zone and forming fins of the channel zone and the second connecting zone, a control electrode arranged in the trenches, the electrode being arranged adjacent to the channel zone and insulated from the semiconductor body, and a breakdown current path connected between the first and second connecting zones and parallel to the channel zone, the current path having least one p-n junction.

### FIELD

The present invention relates to a method for manufacturing a vertical field effect transistor structure and to a corresponding vertical field effect transistor structure.

### BACKGROUND INFORMATION

Power MOSFETs with a vertical channel region (TMOSFETs) are typically used for the application of semiconductors having a wide band gap (e.g. silicon carbide (SiC) or gallium nitride (GaN)) in power electronics.

In the TMOSFET concept, the n+ source region located in a semiconductor material and the p channel region are interrupted by so-called trenches which extend down to the n− drift region. Within the trenches is a gate electrode which is separated from the semiconductor material by a gate oxide and serves for controlling the channel region.

Through a suitable choice of geometry, epitaxy, channel and screening doping, it is possible to optimize on-resistance, threshold voltage, short-circuit resistance, oxide load and breakdown voltage of such TMOSFETs.

FIG. 3 shows a sectional perspective representation of a vertical field effect transistor structure according to German Patent No. DE 102 24 201 B4 as the starting point of the present invention.

The semiconductor component shown in FIG. 3 realizes an n-conducting vertical trench MOSFET having a shielding structure arranged at the trenches. This structure is of course also applicable to a p-conducting MOSFET, wherein the dopings explained below would then be swapped.

The semiconductor component comprises a semiconductor body 100 having an n doped first connecting zone 12, 14. This first connecting zone 12, 14 is more strongly n doped in the region of the rear side of the semiconductor body 100 and forms the n+ drain zone 12 of the MOSFET there, whereas a more weakly n doped n− drift zone 14 adjoins the n+ drain zone 12. The semiconductor body 100 further comprises a p channel zone or body zone 20 which adjoins the n− drift zone 14 and which is formed between the n− drift zone 14 and a strongly n doped second n+ connecting zone 30 formed in the region of the front side. The second n+ connecting zone 30 forms the source zone of the MOSFET.

Starting from the front side 101 of the semiconductor body 100, multiple trenches 60, two of which are shown in FIG. 3, extend through the n+ source zone 30 and the p body zone 20 to the n− drift zone 14 of the semiconductor body 100.

In the region of the sidewalls of the trenches 60, control electrodes 40 are arranged, which connected together form the gate electrode of the MOSFET. These gate electrodes 40 are insulated from the semiconductor body 100 by a gate insulating layer 50 and run in the vertical direction of the semiconductor body from the n+ source zone 30 along the p body zone 20 to the n− drift zone 14 in order to form an electrically conducting channel in the body zone 20 along the side wall of the trench between the n+ source zone 30 and the n− drift zone 14 when a suitable control potential is applied.

The semiconductor component comprises a plurality of similar transistor structures, so-called cells, each having n+ source zones 30, p body zones 20 and gate electrodes 40, wherein a commonality of all the cells in the example is that they have an n− drift zone 14 and an n+ drain zone 12. Here, the n+ source zones 30 of all cells are electrically conductively connected to each other to form a common source zone, and the gate electrodes 40 of all cells are electrically conductively connected to each other to form a common gate electrode.

The semiconductor component shown in FIG. 3 comprises a shielding structure having an electrode 80 formed in each trench 60 and insulated from its respective gate electrode 40 by way of a further insulation layer 70. This electrode 80 extends vertically along the entire length of the trench and, at the bottom of the trench 60, contacts the semiconductor body 100 in the region of the drift zone 14. In this contact region between the electrode 80 and the drift zone 14, a p doped zone 90 is provided which is contacted by the electrode 80 and which completely covers the electrode in this region. The p doped zone 90 and the drift zone 14 or the drain zone 12, respectively, form a diode, the circuit symbol of which is shown in FIG. 3, and which, in the n-conducting MOSFET shown, is polarized in the source-drain direction in the forward direction or in the drain-source direction respectively in the blocking direction. The breakdown voltage of this diode in the drain-source direction can be adjusted via the doping of the p doped zone 90. A JFET is thus formed at the p doped zones, which serves to limit the current through the channel region in the event of a short circuit.

The electrode 80 arranged in the trench 60 is shorted to the n+ source zone 30. To accomplish this, the electrode 80 connects directly to the n+ source zone 30 at the side walls of the trench 60 in the upper region of the trench. The electrode 80, which is preferably made of a metal or polysilicon, in particular n doped or p doped polysilicon, thus simultaneously serves as a terminal contact for the n+ source zone 30 such that, for the purposes of contacting the n+ source zones 30, this electrode 80 can be contacted directly above the trench 60, whereby it is possible to dispense with contact terminals above the semiconductor regions located between the trenches, these regions being the so-called mesa regions.

The semiconductor component further comprises strongly p doped p+ body connecting regions 22, which extend, as is clear from the perspective view in FIG. 4, starting from the p body zone 20, between portions of the n+ source zone 30 to the front side of the semiconductor body 100 and which contact the electrode 80 in the upper region of the trench 60 such that the electrode 80 shorts the p body zone 20 and the n+ source zone 30 via the p+ body connecting regions 22 in order to avoid parasitic bipolar effects in a conventional manner. The semiconductor component eliminates the need for separate contacts in the semiconductor region formed between the trenches, the so-called mesa region, for shorting the n+ source zone 30 and the p body zone 20.

The narrow p+ body connecting regions 22 are sufficient for connecting the p body zone 20 to the electrode 80 so as to achieve the short circuit, making the space required to do so small in the mesa region. The body diode polarity between source 30 and drain 14 created by short-circuiting the n+ source zone 30 and the p body zone 20 is the same as that of the diode of the shielding structure.

The threshold voltage of the shielding structure is set to be less than that of the body diode. When a positive voltage is applied in the source-drain direction, the majority of the current then flows through the diode of the shielding structure, which has a polarity in the forward direction, so that the cross section of the p+ body connecting regions 22 through which the p body zone 20 and the n+ source zone 30 are shorted can be small and therefore implemented in a space-saving manner. The dimensions of this silicon region between the trenches 60 can be reduced in comparison to conventional semiconductor components in this way, which helps to reduce the specific on-resistance of the semiconductor component.

When a positive drain-source voltage is applied, and when a gate potential is applied which is positive relative to a source potential, the conventional semiconductor component works like a conventional MOSFET, the circuit symbol of which is shown in FIG. 3. If the drain-source voltage in a blocking MOSFET exceeds the threshold voltage of the diode formed by the p doped zone 90 and the drift zone 14, a reverse current flows from a drain connection connected to the drain zone 12 through the drift zone 14, the p doped zone 90 and the electrode 80 to a source connection connected to the electrode 80. When a voltage is applied in the reverse direction, i.e. when a voltage is applied that is positive in the source-drain direction, this breakdown structure functions like the body diode, and assumes the majority of the current then flowing, so that the terminal contact for the p body zone 20 can be small and space-saving.

A short circuit can occur in the TMOSFET according to FIG. 3, for example at power-on, without a gate voltage being applied. In this case, a high drain voltage is in effect at the semiconductor component, and a very high short-circuit current can flow if there are no suitable countermeasures, which can lead to the destruction of the component.

Limiting the short-circuit current can be achieved using the JFET formed by the p doped zones 90, wherein the space charge zones emanating from the p doped zone 90 approach one another such that a pinch off of the short circuit current occurs. Thus, in the event of a short circuit, the p doped zones 90 function as p shielding zones.

A general optimization problem with this TMOSFET is that, in the design of each power MOSFET, a compromise must be found between low on-resistance (i.e., high current at low drain voltages) and low short-circuit current (i.e., low current at high drain voltages).

### SUMMARY

The present invention provides a vertical field effect transistor structure and a method for manufacturing a vertical field effect transistor structure.

Preferred further developments of the present invention are disclosed herein.

An underlying feature of the present invention is that the p body connection is designed deeper than the p body region, i.e., it extends into the n− drift zone. Thus, a p-n junction is created below the channel, which reduces the resistance at high drain voltages and thus helps to reduce the short-circuit current. At high drain voltages, a depletion zone thus forms in the n− drift zone, which causes an increase in the resistance of the component. In the event of a short circuit, it is precisely this increase in the resistance that helps to limit the short-circuit current.

The trenches are preferably widened by cyclic oxidation and oxide etching so that the mesas located between the trenches are narrowed down to fins.

According to a preferred further development of the present invention, the reverse current path runs inside the trenches, a respective electrode being arranged in the trenches which is electrically conductively connected to the second connecting zone and which is electrically insulated from the control electrode, and which contacts the doped zone of the second conductivity type at the bottom of the trenches.

In accordance with a further preferred development of the present invention, the body connecting regions of the second conductivity type electrically contact the doped zones of the second conductivity type, wherein the reverse current path runs through the body connecting regions of the second conductivity type and through the doped zones of the second conductivity type. This has the advantage that complex processing of the connection in the trenches for purposes of producing the electrodes is not necessary.

According to a further preferred development of the present invention, the first connecting zone has a less doped drift region and a more doped drain region of the first conductivity type, the doped zones of the second conductivity type are arranged in the drift region, and the body connecting regions of the second conductivity type extend into the drift region.

According to a further preferred development of the present invention, a spreading zone of the first conductivity type is provided between the first connection region and the channel zone. This improves current distribution.

According to another preferred further development of the present invention, the semiconductor body is made of silicon carbide or gallium nitride.

### BRIEF DESCRIPTION OF THE DRAWINGS

Further features and advantages of the present invention are explained below by means of example embodiments with reference to the figures.

FIG. 1A-1H show schematic cross-sectional diagrams for explaining a method for manufacturing a vertical field effect transistor structure and a corresponding vertical field effect transistor structure according to a first example embodiment of the present invention.

FIGS. 2A and 2B show schematic cross-sectional diagrams for explaining a method for manufacturing a vertical field effect transistor structure and a corresponding vertical field effect transistor structure according to a second embodiment of the present invention.

FIG. 3 shows a sectional perspective representation of a vertical field effect transistor structure according to German Patent No. DE 102 24 201 B4 as the starting point of the present invention.

### DETAILED DESCRIPTION OF EXAMPLE EMBODIMENTS

In the figures, identical reference numbers denote identical or functionally identical elements.

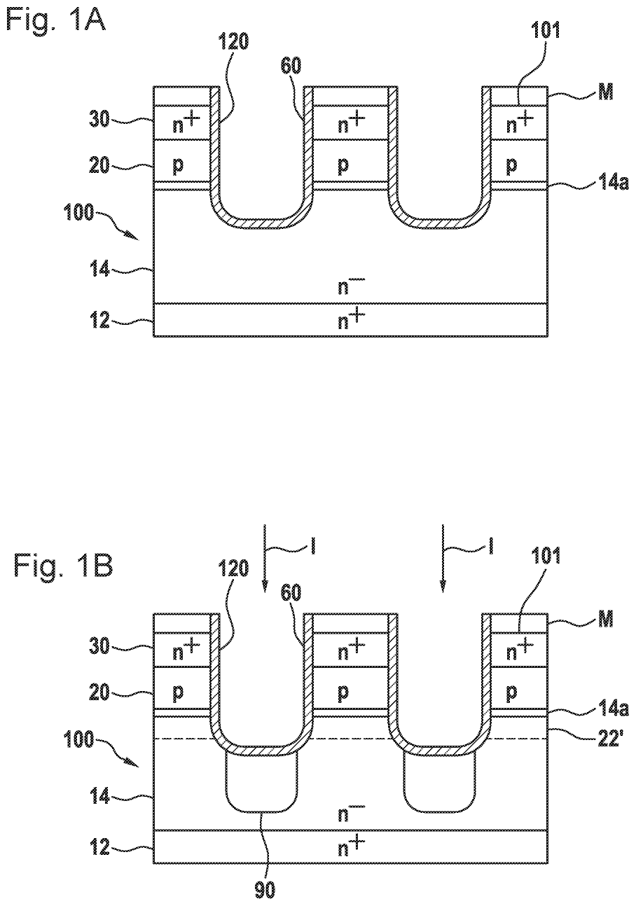

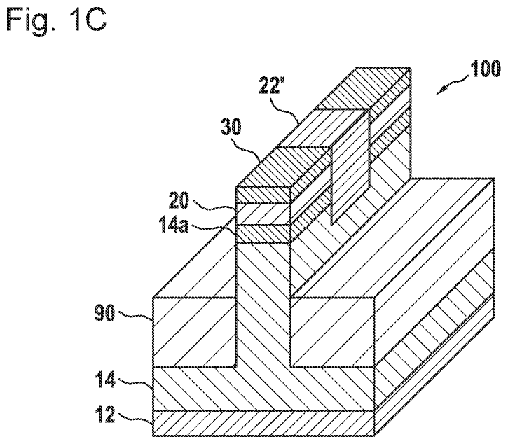

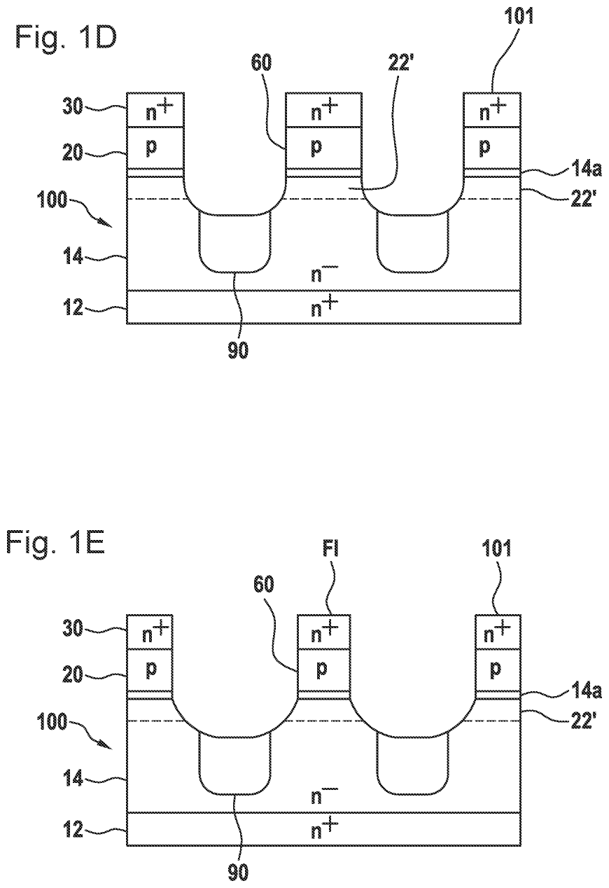

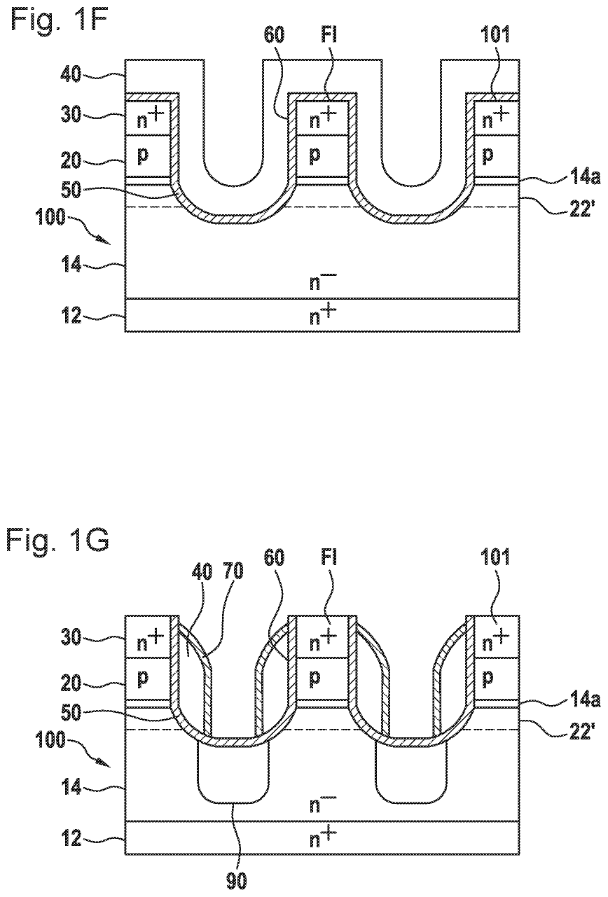

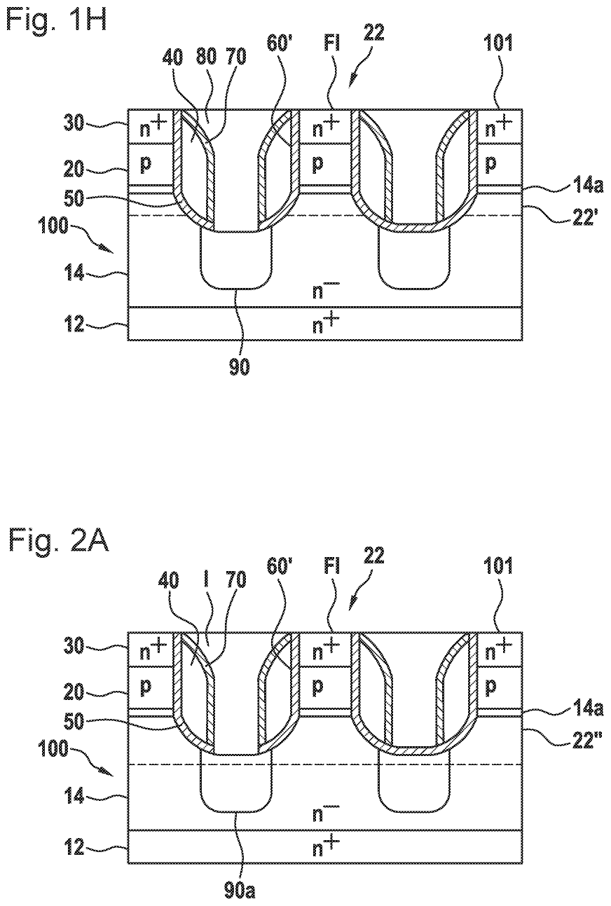

FIGS. 1A-1H show schematic cross-sectional diagrams for explaining a method for manufacturing a vertical field effect transistor structure and a corresponding vertical field effect transistor structure according to an embodiment of the present invention.

FIG. 1A shows a semiconductor body 100, which has a strongly n doped zone 12, the later n+ drain zone, in the region of the rear side, a weaker n doped n− drift zone 14 adjoining the n+ drain zone 12, a p doped zone 20 adjoining the n− drift zone 14, the later body zone, and a strongly n doped zone adjoining the body zone 20, the later n+ source zone 30 on the front side 101. Optionally, an n-spreading zone 14a can be provided between the n− drift zone 14 and the body zone 20, the spreading zone contributing to better current distribution during operation. The spreading zone 14a can also lie deeper in the n− drift zone 14 or reach deeper into it. In particular, it can reach between the p shielding regions 90.

The process state according to FIG. 1A is achieved by providing the semiconductor body 100 in the form of a semiconductor wafer and subsequently performing conventional epitaxy and implantation steps. A hard mask M is used to etch the trenches 60 into the front side 101 using a trench etching process, and then a scattered oxide 120 is deposited on the walls of the trenches 60. Optionally (not shown), another re-implantation step can be performed in order to generate an re-spreading zone in the n− drift zone 14.

According to FIG. 1B, a p implantation I is then performed in order to form p doped zones 90 (p shielding zones) in the n− drift zone 14 below the trenches 60.

In contrast to the conventional structure according to FIG. 3, during the p implantation I, using corresponding openings in the hard mask M, the p body zones 20 are also contacted in the third dimension via p+ doped regions 22′ which alternate with n+ source zones 30 along n+p fin FI.

Also, the p+ doped regions 22′ are implanted substantially deeper than the p+ doped regions 22 according to FIG. 3. In particular, in this embodiment, the p+ doped regions 22′ extend into the n− drift zone 14 as indicated in FIG. 1B by a dashed line and as illustrated in FIG. 1C in a perspective cutaway cross-sectional view.

By way of an annealing step, the p doped zones 90 and the p+ doped regions 22′ can be diffused out and activated.

Referring further to FIG. 1D, the hard mask M and the scattered oxide 120 are removed.

Subsequently, according to FIG. 1E, the trenches 60 are widened, wherein the widened trenches 60′ are delimited laterally by narrowed n+/p mesa regions, which are also called n+/p fin FI. This is done by means of cyclic oxidation and oxide etching of the n+/p mesa regions. This step allows undesired p implantation regions which can originate from the implantation step I according to FIG. 1B to be removed from the side walls of the n+/p mesa regions.

FIG. 1F shows the structure following the deposition of the gate insulating layer 50 and a polysilicon layer 40′ from which the gate electrodes 40 are produced on the side walls of the widened trenches 60′ according to FIG. 1G.

These gate electrodes 40 can be produced by a so-called polyspacer process, for example. For this purpose, using an anisotropic etching process, for example, the polysilicon layer 40 is etched back until the polysilicon layer 40 is removed at the bottom of the trenches 60′, from the front side 101 of the semiconductor body 100, and partially from the side walls in the upper region of the widened trenches 60′. The gate insulating layer 50 is also removed from the front side 101.

Finally, an insulation layer 70, for example an oxide layer, is generated on the exposed regions of the gate electrodes 60. To this end, either the insulation layer 70 is deposited onto the gate electrodes 40 or the gate electrodes 40 are subjected to an oxidation process. Subsequently, the insulation layer 70 is removed from the front side 101 of the semiconductor body 100 and in the bottom region of the widened trenches 60′

Subsequently, the widened trenches 60′ are filled with an electrode material, for example a metal or polysilicon, for purposes of manufacturing the electrodes 80, as shown in FIG. 1H, in order to arrive at the vertical field effect transistor structure according to the embodiment of the present invention.

Advantageously, if the electrodes are made of a metal or n doped silicon, a silicide is advantageously applied to the exposed front side 101 of the semiconductor body 100, at least in the region of the p doped zone, prior to the manufacture of the electrodes 80 in order to obtain good ohmic contact between the electrode 80 and the p doped zone 90 to prevent a p-n junction or Schottky contact from developing at this junction. The contacting of the gate electrodes 40 can occur as in conventional trench transistors, and is not shown here.

The process sequence described above focuses solely on the processes in the cell field. Other processes outside the cell field, such as edge termination, contact pad lead-outs, etc., must be considered. In addition, each step can include multiple sub-steps that are not specifically listed.

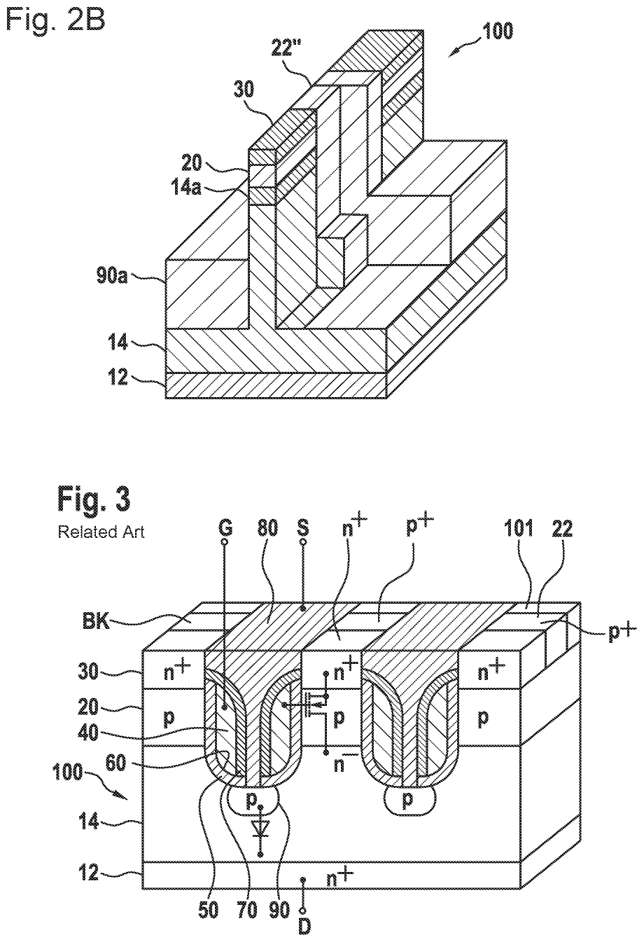

FIGS. 2A and 2B are schematic cross-sectional diagrams for explaining a method of manufacturing a vertical field effect transistor structure and a corresponding vertical field effect transistor structure according to a second embodiment of the present invention.

FIG. 2A shows the process state analogous to FIG. 1F of the completed vertical field effect transistor structure according to the second embodiment.

In contrast to FIG. 1F, according to FIG. 2A, the p+ doped regions 22″ are implanted even deeper into the n− drift zone 14. This results in the p+ doped regions 22″ and the p doped zones 90a touching each other and thus being electrically connected to each other. In this way, it becomes unnecessary to electrically connect the p doped zones 90a (p shielding regions) using the electrodes 80. This is advantageous since complex processing of this connection in the trenches 60′ in order to manufacture the electrodes 80 is now no longer necessary.

Thus, the trenches 60′ according to FIG. 2A are simply filled in with an insulation layer I to obtain a planar front side 101. In addition, additional layers can also be applied for filling and planarization. In particular, in the case of regions 22″ which are implanted deep into the n− drift zones 14 and which contact the p doped zones 90a, it is possible to dispense with bisecting the electrodes 40. In this case (not shown), the trench is completely filled with electrode material and insulated on the surface with an insulation layer I.

FIG. 2B shows, in a perspective cutaway view, the process state analogous to FIG. 1C to make it clear that the p+ doped regions 22″ and the p doped zones 90a contact each other.

Although the present invention has been described by means of preferred embodiment examples, it is not limited thereto. In particular, the materials and topologies mentioned are only exemplary and not limited to the examples explained. The geometries shown are also only exemplary and can be arbitrarily varied as needed.

In the embodiments described above, although the p+ doped regions and the p doped zones were formed in a common implantation step, it is also possible to use two separate implantation steps for this purpose.

1-12. (canceled)

13. A vertical field effect transistor structure, comprising:
a semiconductor body including a first connecting zone and a second connecting zone of a first conductivity type;
a channel zone of the first conductivity type, or of a second conductivity type which is complementary to the first conductivity type, the channel being arranged between the first and the second connecting zones;
a plurality of trenches extending into the semiconductor body, the trenches reaching from the second connecting zone through the channel zone, into the first connecting zone and forming fins of the channel zone and the second connecting zone;
a control electrode arranged in the trenches, the electrode being adjacent to the channel zone and insulated from the semiconductor body;
a reverse current path connected between the first and second connecting zones and parallel to the channel zone, the reverse current path including at least one p-n junction and being configured to conduct when a threshold voltage applied between the first and second connecting zones is reached;
wherein the semiconductor body includes a respective doped zone of the second conductivity type in the first connecting zone below the trenches;
wherein the fins include body connecting regions of the second conductivity type which electrically contact the channel zone and the second connecting zone; and
wherein the body connecting regions of the second conductivity type extend into a drift zone.

14. The vertical field effect transistor structure according to claim 13, wherein the reverse current path runs within the trenches, wherein each of the trenches has a respective electrode arranged therein which is electrically conductively connected to the second connecting zone and is electrically insulated from the control electrode, and which contacts the doped zone of the second conductivity type at a bottom of the trenches.

15. The vertical field effect transistor structure according to claim 13, wherein the body connecting regions of the second conductivity type electrically contact the doped zones of the second conductivity type, and wherein a breakdown current path runs through the body connecting regions of the second conductivity type and through the doped zones of the second conductivity type.

16. The vertical field effect transistor structure according to claim 13, wherein the first connecting zone includes a lower doped drift region and a higher doped drain region of the first conductivity type, the doped zones of the second conductivity type being arranged in the drift region, and wherein the body connecting regions of the second conductivity type extend into the drift region.

17. The vertical field effect transistor structure according to claim 13, wherein a spreading zone of the first conductivity type is provided between the first connection region and the channel zone.

18. The vertical field effect transistor structure according to claim 13, wherein the semiconductor body is made of silicon carbide (SiC) or gallium nitride (GaN).

19. A method of manufacturing a vertical field effect transistor, the method comprising the following steps:
providing a semiconductor body having a first connecting zone and a second connecting zone of a first conductivity type, and a channel zone of the first conductivity type or a second conductivity type complementary to the first conductivity type arranged between the first and second connecting zones;
forming a plurality of trenches extending into the semiconductor body, the trenches reaching from the second connecting zone through the channel zone, into the first connecting zone and forming fins of the channel zone and the second connecting zone;
forming a control electrode arranged in the trenches, the electrode being located adjacent to the channel zone and insulated from the semiconductor body;
forming a reverse current path connected between the first and second connecting zones and parallel to the channel zone, the reverse current path including at least one p-n junction and being configured to conduct when a threshold voltage between the first and second connecting zones is reached;
forming a respective doped zone of the second conductivity type in the first connecting zone below the trenches;
forming body connecting regions of the second conductivity type in the fins, the body connecting regions electrically contacting the channel zone and the second connecting zone; and
wherein the body connecting regions of the second conductivity type are formed such that they extend into a drift zone.

20. The method according to claim 19, wherein the doped zones of the second conductivity type and the body connecting regions of the second conductivity type are formed in a common implantation step.

21. The method according to claim 19, wherein the reverse current path runs in the trenches, wherein in the trenches, a respective electrode is arranged which is electrically conductively connected to the second connecting zone and which is electrically insulated from the control electrode, and which contacts the doped zone of the second conductivity type at a bottom of the trenches.

22. The method according to claim 19, wherein the body connecting regions of the second conductivity type are formed such that they electrically contact the doped zones of the second conductivity type, and wherein a breakdown current path runs through the body connecting regions of the second conductivity type and through the doped zones of the second conductivity type.

23. The method according to claim 19, wherein the first connecting zone includes a lower doped drift region and a higher doped drain region of the first conductivity type, the doped zones of the second conductivity type being arranged in the drift region, and wherein the body connecting regions of the second conductivity type extend into the drift region.

24. The method according to claim 19, wherein a spreading zone of the first conductivity type is provided between the first connection region and the channel zone.
